(19) United States
(12) Patent Application Publication
(10) Pub. No.: US 2011/0031006 A1
(43) Pub. Date: Feb. 10, 2011

(54) CABLE ASSEMBLY WITH CABLE HOLDER HAVING ANTI-EMI FUNCTION

(75) Inventors: CHI-MING CHEN, Tu-Cheng (TW); JUN ZONG, Kunshan (CN)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION INDUSTRY CO., LTD., Tu-Cheng (TW)

(21) Appl. No.: 12/853,465

(22) Filed: Aug. 10, 2010

(30) Foreign Application Priority Data
Aug. 10, 2009 (CN) 200920307636.5

(51) Int. Cl. H05K 9/00; H01B 9/02

(52) U.S. Cl. 174/350; 174/107; 174/135

(57) ABSTRACT

A cable assembly (100) comprises a cable (13), a filter (11) made of magnetic material for anti-EMI and surrounding the cable (13), an insulative main body (12) enclosing the filter (11), at least a pair of flexible prongs (121) extending outwardly from the insulative main body (12); wherein the pair of the flexible prongs (121) with the insulative main body (12) together forming a clip (122,123) with a hole for receiving cables (131,133).

### BACKGROUND OF THE INVENTION

1. Field of the Invention

The present invention relates to a cable assembly , and more particularly to a cable assembly with a cable holder which has anti-EMI function.

2. Description of Prior Art

Cables are used in various electronic devices for power and/or signal transmission. For computer systems , a number of cables are needed to connect different elements therein. These cables may twist together and therefore bring some trouble to a worker. Usually, an attachment tape is adopted to tie the cables, however, It's inconvenient for the worker to finish the process. In other aspect, there are electromagnetic interference(EMI) between cables, which may influence signal transmitting.

Hence, It would be desirable to provide a cable assembly, which makes it easier for a user to retain cables and provides a structure for suppressing the electromagnetic interference

### SUMMARY OF THE INVENTION

An object of the present invention is to provide a cable assembly with a cable holder which has anti-EMI function.

To achieve the aforementioned object, the present invention provides a cable assembly comprising a cable, a filter made of magnetic material for anti-EMI and surrounding the cable, an insulative main body enclosing the filter, at least a pair of flexible prongs extending outwardly from the insulative main body; wherein the pair of the flexible prongs with the insulative main body together forming a clip with a hole for receiving one or more cables.

Additional novel features and advantages of the present invention will become apparent by reference to the following detailed description when taken in conjunction with the accompanying drawings.

### BRIEF DESCRIPTION OF THE DRAWINGS

FIG. 1 is a assembled, perspective view of a cable assembly aligning a cable in accordance with a first embodiment of the present invention;

FIG. 2 is an exploded, perspective view of FIG. 1;

FIG. 3 is a assembled, perspective view of a cable assembly aligning a cable in accordance with a second embodiment of the present invention ; and

FIG. 4 is an exploded, perspective view of FIG. 3.

### DETAILED DESCRIPTION OF THE INVENTION

Reference will now be made in detail to the preferred embodiment of the present invention.

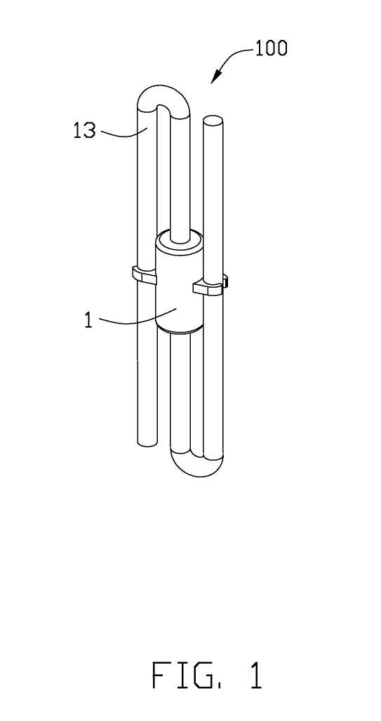

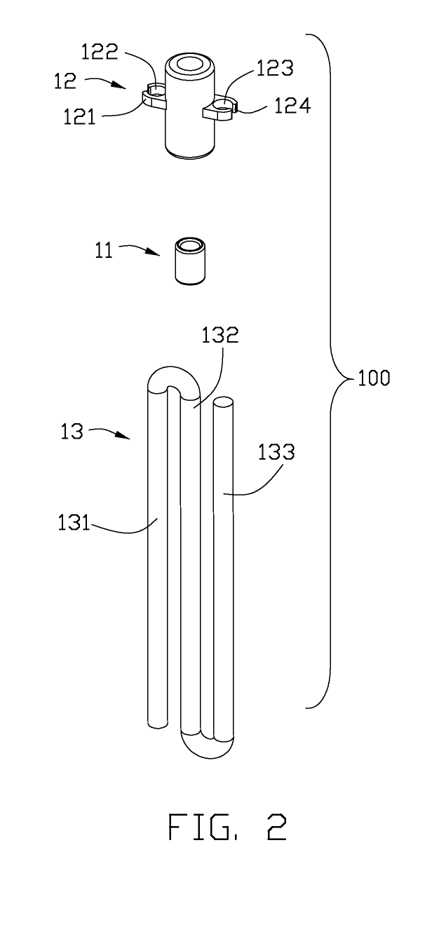

Referring to FIGS. 1-2, a cable assembly 100 in accordance with a first embodiment of the present invention has a cable holder 1 mounted to a cable 13. The cable holder 1 comprises a filter 11 and an insulative main body 12 enclosing the filter 11. The filter 11 is cylindrical and made of magnetic materials for anti-EMI. The insulative main body 12 is cylindrical and molded on the filter 11. Two pairs of flexible prongs 121 separately extend outwardly from the opposite sides of the insulative main body 12 and with the insulative main body 12 together to form a first clip 122 and a second clip 123 in the opposite direction. Each clip is generally U-shaped with a round hole for receiving one or more cables and an opening 124 at a bottom of the U-shaped structure.

The cable holder 1 is fixedly attached to the cable 13 , which is bent into a first part 131, a second part 132 and a third part 133. The filter 11 of the cable holder 1 surrounds the second part 132 , the insulative main body 12 is molded on the filter 11 and the second part 132 of the cable 13. By slightly flexing the flexible prongs 121, the first part 131 and the third part 133 of the cable 13 can be retained by or removed from the first and second clip 122,123. With the flexible prong 121 in an unflexed state, the opening 124 is smaller than the cable 13 to prevent any single cable escaping from the first and second clip 122,123.

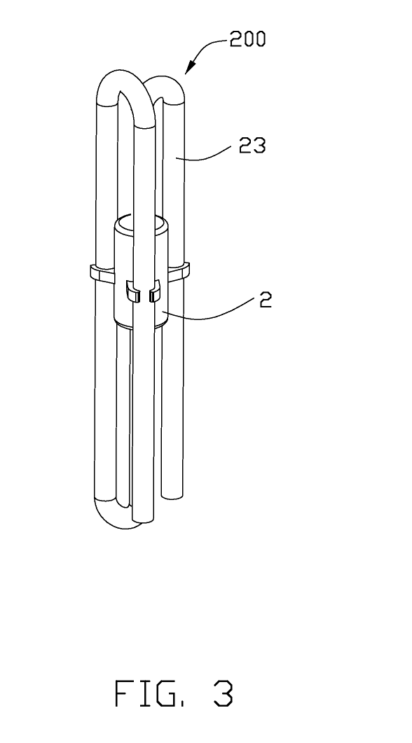

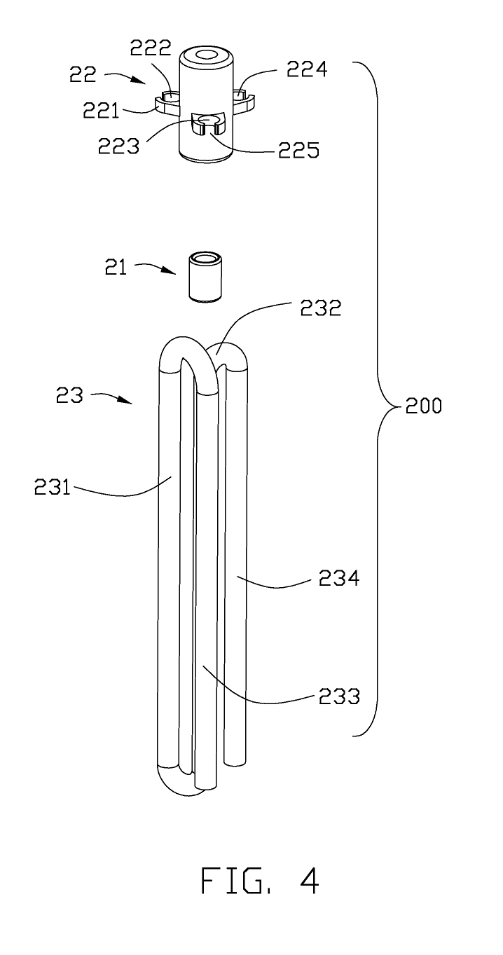

Referring to FIGS. 3-4, a cable assembly 200 in accordance with a second embodiment of the present invention comprises a cable holder 2 mounted to a cable 23. The cable holder 2 includes a filter 21 made of magnetic materials for anti-EMI and a cylindrical insulative main body 22 enclosing the filter 21. Three pairs of flexible prongs 221 separately extend outwardly from the insulative main body 12 and with the insulative main body together to form a first clip 222 ,a second clip 223 and a third clip 224 symmetrically extending along three different direction. Each clip is generally U-shaped with a round hole for receiving one or more cables and an opening 225 at the bottom of the U-shaped structure.

The cable holder 2 is fixedly attached to the cable 23 , which is bent into a first part 231, a second part 232, a third part 233 and a fourth part 234. The filter 21 of the cable holder 2 surrounds the second part 232, and the insulative main body 22 is molded on the filter 11. By slightly flexing the flexible prongs 221, the first part 231, the third part 233 and the fourth part 234 of the cable 23 can be separately held in or removed from the first, second and third clip 222,223,224. With the flexible prong 221 in an unflexed state, the opening 225 is of a size to prevent any single cable passing through the first, second and third clip 222,223,224.

In both of above embodiments, although the clip 122,123,222,223,224 is shown as U-shaped, other shapes may be used, including generally circular, oval, and square, for example, and the number of the clips on one cable holder 1,2 may be one, four, and so on. Furthermore, although one cable holder 1,2 is shown with one cable 13,23, two or more cables may be installed on two or more cable holders, spaced, for example. However, use of the cable holder 1,2 could save more space in a device and provide a good performance on anti-EMI.

What is claimed is:

1. A cable assembly, comprising:
a cable;
a filter made of magnetic material for anti-EMI and surrounding the cable;
an insulative main body enclosing the filter;
at least a pair of flexible prongs extending outwardly from the out surface of the insulative main body; wherein
the pair of the flexible prongs cooperate with the insulative main body together to form a clip with a hole for receiving one or more cables.

2. The cable assembly as claimed in claim 1, wherein said cables received in the hole could be retained by or removed from said clip by flexing the flexible prongs.

3. The cable assembly as claimed in claim 2, wherein there is an opening defined in the clip which has a smaller size than the cable to prevent any single cable passing through while the flexible prongs in an unflexed state.

4. The cable assembly as claimed in claim 3, wherein said cable holder is fixedly attached to a cable with the insulative main body molded on the filter and the cable.

5. The cable assembly as claimed in claim 4, wherein said cable holder has two clips with openings towards opposite directions.

6. The cable assembly as claimed in claim 4, wherein said cable holder has three clips symmetrically formed on the insulative main body, and the three clips have openings towards three directions.

7. The cable assembly as claimed in claim 6, wherein said clips are disposed on a plane.

8. The cable assembly as claimed in claim 7, wherein said each clip is U-shaped with the opening at the bottom of the U-shaped structure.

9. The cable assembly as claimed in claim 8, wherein said hole of the clip is round-shaped and has a bigger size than the cable.

10. A cable assembly, comprising:
a cable extending along a first direction;
a cable holder including a filter enclosed in an insulative main body, the cable passing through the filter along the first direction, and bent toward the insulative main body to extend along a second direction opposite to the first direction;
at least one clip formed on a lateral side of insulating main body to retain the cable.

11. The cable assembly as claimed in claim 10, wherein the cable includes a first part, a second part and a third part, and the second part is enclosed by the cable holder, the first part and the third part are disposed at lateral sides of the cable holder and held by two clips formed on the cable holder.

12. The cable assembly as claimed in claim 10, wherein there are three clips formed on said insulating main body.

13. The cable assembly as claimed in claim 12, wherein the cable includes a first part, a second part, a third part and a fourth part, and the second part is enclosed by the filter of the cable holder, the first part, the third part and the fourth part are disposed at lateral sides of the cable holder and held by said three clips formed on the insulating main body of the cable holder.

14. A cable assembly comprising:
a cable including a conductor held in an insulator; and
a cable holder enclosing a filter which is made of magnetic material for anti-EMI (Electro-Magnetic interference) and through which said cable extends; wherein
at least one clip is integrally formed on an exterior surface of the cable holder and is dimensioned to comply with a diameter of the cable for properly holding a portion of said cable in position when said cable is folded around the cable holder.

15. The cable assembly as claimed in claim 14, wherein said at least one clip includes a pair of clips oppositely diametrically arranged with each other.

16. The cable assembly as claimed in claim 15, wherein said pair of clip are located at a same axial position with regard to the cable holder.

17. The cable assembly as claimed in claim 16, wherein said cable have two U-shaped turns by two opposite ends of the cable holder in said axial direction.

18. The cable assembly as claimed in claim 14, wherein said at least one clip includes three clips symmetrically arranged with one another around a center.

19. The cable assembly as claimed in claim 18, wherein said pair of clip are located at a same axial position with regard to the cable holder.

20. The cable assembly as claimed in claim 19, wherein said cable have three U-shaped turns by two opposite ends of the cable holder in said axial direction.
